(19) United States
(12) Patent Application Publication
(10) Pub. No.: US 2023/0420617 A1
(43) Pub. Date: Dec. 28, 2023

(54) NITRIDE BASED ULTRAVIOLET LIGHT EMITTING DIODE WITH AN ULTRAVIOLET TRANSPARENT CONTACT

(71) Applicant: THE REGENTS OF THE UNIVERSITY OF CALIFORNIA, OAKLAND, CA (US)

(72) Inventors: Michael Iza, Goleta, CA (US); Matthew S. Wong, Santa Barbara, CA (US); Steven P. DenBaars, Goleta, CA (US); Shuji Nakamura, Santa Barbara, CA (US)

(73) Assignee: THE REGENTS OF THE UNIVERSITY OF CALIFORNIA, OAKLAND, CA (US)

(21) Appl. No.: 18/248,817

(22) PCT Filed: Oct. 29, 2021
(86) PCT No.: PCT/US21/57267

§ 371 Date: Apr. 12, 2023

Related U.S. Application Data
(60) Provisional application No. 63/107,860, filed on Oct. 30, 2020.

(51) Int. Cl. H01L 33/42

(52) U.S. Cl. CPC H01L 33/42; H01L 33/32

(57) ABSTRACT

A nitride-based ultraviolet light emitting diode (UVLED) with an ultraviolet transparent contact (UVTC). The nitride-based UVLED is an alloy composition of (Ga, Al, In, B)N semiconductors, and the UVTC is composed of an oxide with a bandgap larger than that emitted in an active region of the nitride-based UVLED, wherein the oxide is an alloy composition of (Ga, Al, In, B, Mg, Fe, Si, Sn)O semiconductors, such as Ga₂O₃.

### CROSS REFERENCE TO RELATED APPLICATIONS

This application claims the benefit under 35 U.S.C. Section 119(e) of the following co-pending and commonly-assigned application:

U.S. Provisional Application Ser. No. 63/107,860, filed on Oct. 30, 2020, by Michael Iza, Matthew Wong, Steve P. DenBaars, and Shuji Nakamura, entitled “NITRIDE BASED ULTRAVIOLET LIGHT EMITTING DIODE WITH AN ULTRAVIOLET TRANSPARENT CONTACT,” attorneys' docket number G&C 30794.0787USP1 (UC 2021-567-1);
which application is incorporated by reference herein.

### BACKGROUND OF THE INVENTION

### 1. Field of the Invention

This invention relates to a nitride-based ultraviolet light emitting diode (UVLED) with an ultraviolet transparent contact (UVTC) resulting in enhanced performance.

### 2. Description of the Related Art

As used herein, the terms “nitride” or “III-nitride” refers to any alloy composition of the (Ga, Al, In, B)N semiconductors having the formula GaₙAlₓIn_{y}B_{z}N where:

0≤n≤1,0≤x≤1,0≤y≤1,0≤z≤1,and n+x+y+z=1

Nitride-based UVLEDs have recently become of great interest due to the many commercial applications. However, there remain significant challenges to the realization of high efficiency nitride-based UVLEDs. Chiefly among these challenges is the lack of a transparent electrical contact. Lack of a transparent contact leads to a decrease in the external quantum efficiency by reducing the light extraction efficiency of these devices.

In conventional nitride-based UVLEDs, a metal mirror is used as an electrical contact. The metal mirror aids in extracting the light emission from the active region of the device by allowing the emitted light to be reflected to a given direction. These metal mirrors are often made of silver and/or aluminum. However, these mirrors often have to incorporate other metals in order to obtain a low resistance electrical contact to the semiconductor material. Because of this, metals such as nickel and gold are mixed or deposited prior to the deposition of the mirror in order to obtain a low resistance electrical contact to the semiconductor. These additional metals are not transparent to the emitted photons and the emitted photons are thus absorbed by these layers. This results in a significant decrease in the efficiency of the device. Even if good electrical contact can be formed, the light reflected from the mirror layers can be re-absorbed by the emitting layer (active region) because the photon energy is almost same as the band-gap energy of the light emitting species, such as nitride-based multi-quantum wells (MQWs). The re-absorption of photons results in a reduction of device efficiency.

In addition to metal mirrors, dielectric mirrors can be employed. However, due to the poor electrical contact and electrical properties, dielectric mirrors are not suitable for high efficiency devices. Thus, a mirror with high reflectivity and low electrical contact resistance is challenging to realize.

Transparent contact layers have been achieved for LEDs emitting in the visible range (from about 380 nm to 740 nm). These layers are typically fabricated by use of Indium Tin Oxide (ITO), which is transparent to wavelengths greater than about 380 nm. However, these layers cannot be employed for use in nitride-based UVLEDs due to their high absorption in the UV radiation spectrum (from about 220 nm to 380 nm).

Another way to improve the transparency of nitride-based UVLEDs is to insert tunnel junction layers above the p-type II-nitride layers. This is typically achieved by the deposition of a highly doped n-type layer above the p-type III-nitride layer, which are transparent to the emitted photons. Electrical contact and current spreading can then occur in the higher conductivity n-type layer. However, this technique is difficult to perform due to the fact that, as deposited, p-type magnesium (Mg) doped III-nitrides are highly resistive. Thus, complex processes such as regrowth by Molecular Beam epitaxy (MBE) and/or side wall exposure need to be performed in order to create a low resistance p-type layer.

As a result, there is a need for improved device design structures on nitride-based devices, wherein the device structure minimizes the deleterious effects present in conventional light emitting nitride-based device structures emitting in the UV range of the radiation spectrum. The present invention satisfies this need.

### SUMMARY OF THE INVENTION

The present invention discloses a nitride-based UVLED with a UVTC that is transparent to ultraviolet light. The UVTC may be composed of an oxide with a bandgap larger than an active region emitting UV light.

As used herein, the term “oxide” refers to any alloy composition of the (Ga, Al, In, B, Mg, Fe, Si, Sn)O semiconductors having the formula GaₙAlₛInₜBᵤMgᵥFe_{w}SiₓSn_{y}O_{z} where:

0≤n≤1,0≤s≤,0≤t≤1,0≤v≤1,0≤w≤1,0≤x≤1,0≤y≤1, 0≤z≤1,and n+s+t+u+v+w+x+y+z=1

The UVTC may comprise one or multiple layers or regions having varying or graded (Ga, Al, In, B, Mg, Fe, Si, Sn)O compositions, or one or more layers or regions of similar (Al, Ga, In, B, Mg, Fe, Si, Sn)O compositions, or a heterostructure comprising layers or regions of dissimilar (Ga, Al, In, B, Mg, Fe, Si, Sn)O compositions.

For example, the UVTC may be composed of Gallium Oxide (Ga₂O₃), as well as different structures and/or phases of Ga₂O₃, such as alpha, beta, gamma, delta, and epsilon. The UVTC may be composed of different crystal orientations of Ga₂O₃, such as (−201), (001), or (010).

The UVTC may be comprised of unintentionally doped or intentionally doped regions, with elements such as tin, iron, magnesium, silicon, oxygen, carbon, and/or zinc.

The UVTC region may be grown using deposition methods comprising hydride vapor phase epitaxy (HVPE), metal organic chemical vapor deposition (MOCVD), MBE, sputtering, atomic layer deposition (ALD), and/or electron beam deposition (EBD). The UVTC may also be mechanically bonded to the device.

The present invention also minimizes internal reflections within the UVLED by eliminating mirrors and/or mirrored surfaces, in order to minimize re-absorption of the UVLED's light by the emitting layer (or active region) of the UVLED. To assist in minimizing internal reflections, the UVLED may include one or more UVTC layers, wherein the UVTC layer is shaped, patterned, textured or roughened to increase the light extraction. Further, the UVLED may include an ultraviolet transparent substrate, wherein the ultraviolet transparent substrate is shaped, patterned, textured or roughened to increase the light extraction.

Multi-directional UV light can be extracted from one or more surfaces of the UVLED. Specifically, the UV light may be extracted from multiple sides of the UVLED, namely, the top (front) and bottom (back) sides of the UVLED.

The UVLED may reside on an ultraviolet transparent plate or in a lead frame that allows the light to be extracted from multiple sides of the UVLED. All layers of the UVLED may be transparent for an ultraviolet emission wavelength, except for an emitting layer or active region.

The UVLED may be embedded in or combined with a shaped optical element comprising an epoxy, glass, silicon or other ultraviolet transparent material molded into a sphere, inverted cone or other shape. The shaped optical element may be shaped, patterned, textured or roughened to increase the light extraction.

Another embodiment of the present invention comprises an n-type region, a p-type region, at least one active region, a second n-type region located on or above the p-type region that forms a tunnel junction with the p-type region, and at least one UVTC region which is transparent to ultraviolet light located on or above the second n-type region.

The structure may further comprise an optical device grown in any crystallographic I-nitride direction, such as on a polar c-plane, or on a nonpolar plane such as a-plane or m-plane, or on any semipolar plane.

The object of this invention is to enhance the light emitting output power of ultraviolet light emitting devices, such as UVLEDs. Improving the light emission efficiency leads to an improvement in the electronic efficiency characteristics of the ultraviolet light emitting semiconductor, and in turn can lead to the expansion of ultraviolet semiconductor device applications into various commercial products.

### BRIEF DESCRIPTION OF THE DRAWINGS

Referring now to the drawings in which like reference numbers represent corresponding parts throughout.

FIG. 1A is a cross-sectional schematic of a first nitride-based semiconductor device of the present invention, comprising of a substrate, an n-type region, an active region, a p-type region, and a UVTC region, and FIG. 1B is an enlarged view of a portion of the active region of FIG. 1A.

FIG. 2A is a cross-sectional schematic of a second nitride-based semiconductor device of the present invention, comprising a substrate, a first n-type region, an active region, a p-type region, a second n-type region, and a UVTC region, and FIG. 2B is an enlarged view of a portion of the active region of FIG. 2A.

FIG. 3 is a flowchart that describes a method for fabricating an embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes nitride-based light emitting device structures incorporating a UVTC region on or above a p-type region. The present invention also describes nitride-based light emitting device structures incorporating a tunnel junction comprised of a second n-type region on or above the p-type region, with a UVTC region on or above the second n-type region. The use of the UVTC region offers a means of improving nitride-based light emitting device performance by greatly enhancing device output power at a constant current.

### TECHNICAL DESCRIPTION

### First Embodiment

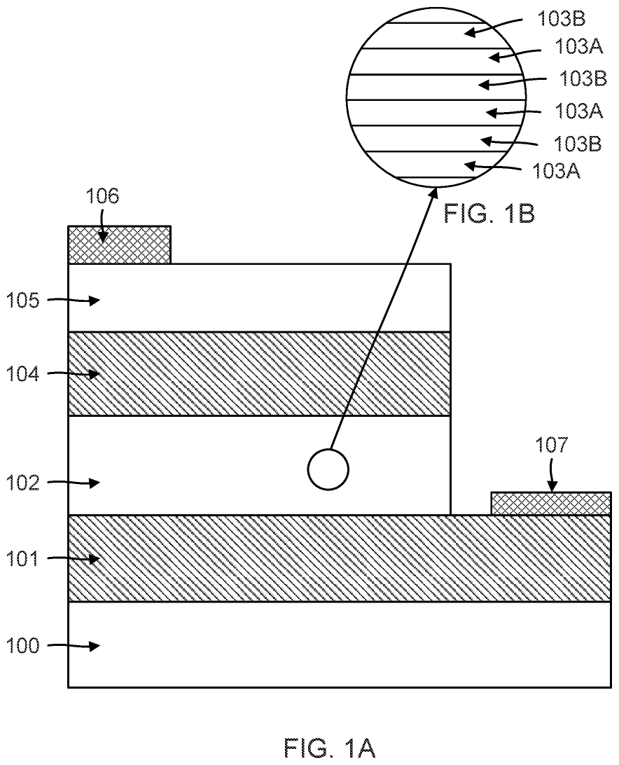

FIG. 1A is a schematic sectional view showing the structure of a first nitride-based semiconductor device (an LED device) according to a first embodiment of the present invention. This LED comprises a substrate 100; an n-type region 101 composed of AlₓIn_{y}Ga_{1-x-y}N (0≤x≤1 and 0≤y≤1) doped with silicon; an active region 102 comprised of a multiple quantum well structure composed of AlₓIn_{y}Ga_{1-x-y}N (0≤x≤1 and 0≤y≤1), which includes alternating layers of well regions 103A and barrier regions 103B as shown in the enlarged view of FIG. 1B; a p-type region 104 composed of AlₓIn_{y}Ga_{1-x-y}N (0≤x≤1 and 0≤y≤1) doped with magnesium; a UVTC region 105 composed of Ga₂O₃; and electrodes 106 and 107.

The substrate 100 may contain some silicon, gallium, indium, germanium, oxygen, or aluminum. The substrate 100 may be oriented in various crystal orientations such as polar, semipolar, or nonpolar. Additionally, the substrate 100 may be a patterned substrate 100. The substrate 100 may be subsequently removed, so that the device can be flip-chip mounted to a carrier or other substrate. An exposed region resulting from the removing of the substrate 100 may be patterned. The carrier may be separated into singulated portions to form light emitting devices separated from one another, with each of the light emitting devices mounted to a respective portion of the carrier.

The III-nitride n-type region 101 has a larger bandgap than the active region 102. This allows for the n-type region 101 to not absorb any of the light emitted from the active region 102.

The III-nitride p-type region 104 also has a larger bandgap than the active region 102. This allows for the p-type region 104 to not absorb any of the light emitted from the active region 102.

In addition, the UVTC region 105 has a larger bandgap than the active region 102. This allows for the UVTC region 105 to not absorb any of the light emitted from the active region 102. The UVTC region 105 may be doped with tin or other dopants such as magnesium, boron, silicon, carbon, zinc, iron, or silicon.

### Second Embodiment

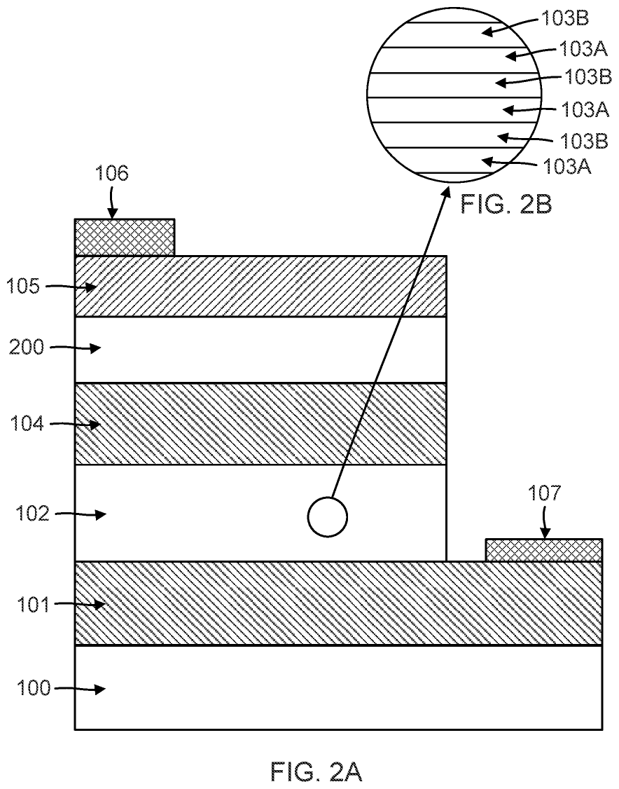

FIG. 2A is a schematic sectional view showing the structure of a second nitride-based semiconductor device (an LED device) according to a second embodiment of the present invention. This LED is comprised of a substrate 100; a first n-type region 101 composed of AlₓIn_{y}Ga_{1-x-y}N (0≤x≤1 and 0≤y≤1) doped with silicon; an active region 102 comprised of a multiple quantum well structure composed of AlₓIn_{y}Ga_{1-x-y}N (0≤x≤1 and 0≤y≤1), which includes alternating layers of well regions 103A and barrier regions 103B as shown in the enlarged view of FIG. 2B; a p-type region 104 composed of AlₓIn_{y}Ga_{1-x-y}N (0≤x≤1 and 0≤y≤1) doped with magnesium; a second n-type region 200 composed of AlₓIn_{y}Ga_{1-x-y}N (0≤x≤1 and 0≤y≤1); a UVTC region 105 composed of Ga₂O₃; and electrodes 106 and 107.

The substrate 100 may contain some silicon, gallium, indium, germanium, oxygen, or aluminum. The substrate 100 may be oriented in various crystal orientations such as polar, semipolar, or nonpolar. Additionally, the substrate 100 may be a patterned substrate 100. The substrate 100 may be subsequently removed, so that the device can be flip-chip mounted to a carrier or other substrate. An exposed region resulting from the removing of the substrate 100 may be patterned. The carrier may be separated into singulated portions to form light emitting devices separated from one another, with each of the light emitting devices mounted to a respective portion of the carrier.

In this embodiment, the second n-type region 200 forms a tunnel junction with the p-type region 104. In addition, the second n-type region 200 has a larger bandgap than the active region 102, which allows for the second n-type region 200 to not absorb any of the light emitted from the active region 102.

In this embodiment, a pattern can be formed by properly masking the second n-type region 200 with a periodic pattern comprised of stripes, circles, hexagons, or other patterns, such that subsequent deposited regions, such as the UVTC region 200, preferentially form on the unmasked regions of the second n-type region 200. Masking materials can be composed of silicon dioxide, for example.

The UVTC region 105 may be located on or above the second n-type region 200, wherein the second n-type region 200 is completely covered by the UVTC region 105. Further steps may then be performed, such as etching, in order to expose the second n-type region 200. These steps may include properly masking the UVTC region 105, followed by reactive ion etching (RIE) to remove a portion of the UVTC region 106 in order to expose the second n-type region 200. Further, the UVTC region 105 may be formed by etching periodic patterns into the UVTC region 105, which are comprised of stripes, circles, hexagons, or another pattern.

Process Steps

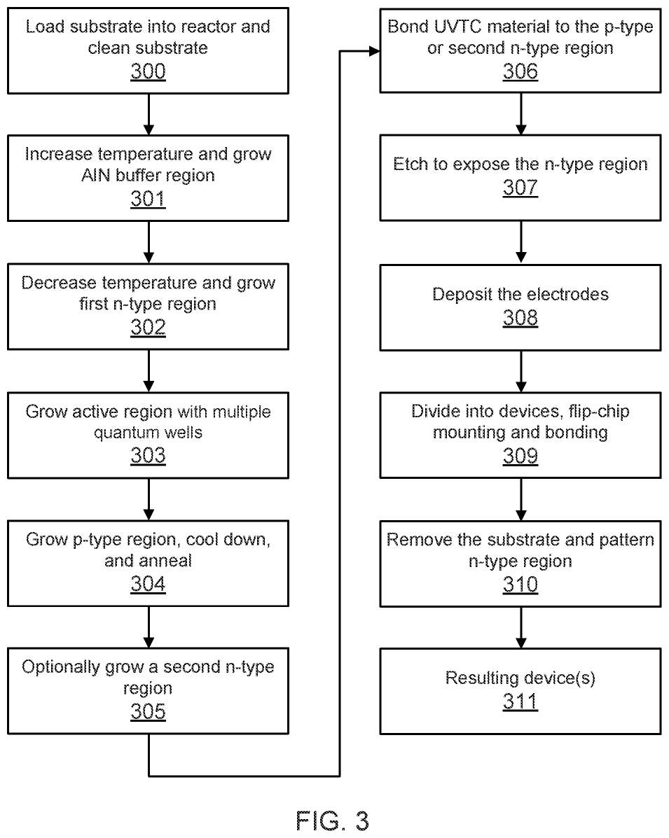

FIG. 3 is a flowchart that describes a method for fabricating an embodiment of the present invention.

In Block 300, the substrate 100 is loaded in a metal organic vapor phase epitaxy (MOVPE) reactor and cleaned. For example, a sapphire (Al₂O₃) substrate 100 is set in the MOVPE reactor and the temperature of the substrate 100 is increased to 1200° C. with hydrogen flow to clean the substrate 100. Instead of a sapphire substrate, the substrate 100 may be a patterned substrate or a substrate having its principal surface represented by an R-face or A-face, an insulating substrate of, for example, spinel (MgAl₂O₄), or a semiconductor substrate of, for example, silicon carbide (SiC) (including 6H, 4H, or 3C), silicon (Si), zinc oxide (ZnO), gallium arsenide (GaAs), gallium oxide (Ga₂O₃), or gallium nitride (GaN).

In Block 301, the temperature is increased to 1250° C. and a first buffer region made of aluminum nitride (AlN), which has a thickness of about 800 nm, is formed by growth on or above the substrate 100, using hydrogen as a carrier gas, and ammonia and trimethylaluminum (TMAl) as material gases. Such a buffer region may be omitted, depending on the kind of the substrate, the growing method, etc.

In Block 302, after growing the buffer region, only TMAl is stopped and the temperature is decreased to 1175° C., wherein the first n-type region 101, comprised of InₓAl_{y}Ga_{1-x-y}N, where 0≤x≤1, 0≤y≤1, is formed on or above the substrate 100. In one embodiment, the first n-type region 101, composed of AlₓGa₁₋ₓN, where x=0.5, doped with silicon (Si) to 1×10¹⁹/cm³, and having a thickness of 300 nm, is grown using ammonia and TMAl as material gases in the same way as in the previous step, and disilane gas as an impurity gas. The composition is not specifically limited to that composition. In such a case, the II-nitride semiconductor region having a minimized crystal defect can easily be obtained.

The thickness of the n-type region 101 is not specifically limited to any thickness. Moreover, the n-type impurity may be desirably doped in with a high concentration to the degree that the crystal quality of the III-nitride semiconductor is not deteriorated and preferably in the concentration between 1×10¹⁸/cm³ and 5×10²¹/cm³.

Next, in Block 303, an active region 102, comprised of InₓAl_{y}Ga_{1-x-y}N, where 0≤x≤1, 0≤y≤1, is formed on or above the n-type region 101. In one embodiment, the active region 102, with a multiple quantum well structure having a total thickness of 30 nm, is grown by laminating alternately five barrier regions 103B and three well regions 103A in the order of barrier region 103B, well region 103A, barrier region 103B, etc., and finishing on a barrier region 103B. The quantum barrier regions 103B, composed of undoped AlₓGa₁₋ₓN, with x=0.5, having a thickness of 8 nm, are grown at 1175° C., and the quantum well regions 103A, composed of undoped AlₓGa₁₋ₓN, with x=0.6, having a thickness of 2.5 nm, are grown using trimethylgallium (TMG), TMAl and ammonia.

In this embodiment, the active region 102 is grown by laminating the barrier region 103B first, but may be grown by laminating the well region 103A first and also last or the order may begin with the barrier region 103B and end with the well region 103A. Thus, the order of depositing the barrier regions 103B and well regions 103A is not specifically limited to a particular order.

The well regions 103A are set to have a thickness of not greater than 10 nm, preferably not greater than 7 nm, and more preferably not greater than 5 nm. A thickness of greater than 10 nm may make it difficult to increase the output of the device. On the other hand, the barrier regions 103B are set to have a thickness of not greater than 30 nm, preferably not greater than 25 nm, and most preferably not greater than 20 nm.

Subsequently, in Block 304, the p-type region 104, comprised of InₓAl_{y}Ga_{1-x-y}N, where 0≤x≤1, 0≤y≤1, is formed on or above the active region 102. In one embodiment, the p-type region 104, composed of p-type AlₓGa₁₋ₓN, with x=0.5, doped with Mg to 1×10²⁰/cm³, is grown at 1075° C., using TMG, TMAl, ammonia, and Bis(cyclopentadienyl)magnesium (Cp₂Mg), to a thickness of 100 nm. In such a case, a III-nitride semiconductor region having minimized crystal defects can be obtained.

Once the reactor has cooled, the epitaxial structure is removed and annealed in a hydrogen deficient atmosphere for 3 minutes at a temperature of 900° C. in order to activate the p-type region 104.

After annealing the p-type region 104, Block 305 is the optional step of forming the second n-type region 200, composed of InₓAl_{y}GaN (0≤x, 0≤y, x+y<1), on or above the p-type region 104. In one embodiment, the second n-type region 200 is grown in a manner similar to the first n-type region 101 and has a similar composition. Like the first n-type region 101, the second n-type region 200 may not be specifically limited to that composition. In one embodiment, the second n-type region 200 forms a tunnel junction with the p-type region 104.

Subsequently, in Block 306, the epitaxial structure is loaded into a bonding system along with the UVTC material, and the UVTC region 105 is formed on or above either the p-type region 104 or the second n-type region 200, wherein the temperature of the epitaxial structure and the UVTC material is heated to 700° C., so as to bond the UVTC region 105 into contact with either the p-type region 104 or the second n-type region 200. Once the bonding system has cooled, the resulting structure is removed.

In one embodiment, the UVTC material is comprised of an alloy composition of the (Ga, Al, In, B, Mg, Fe, Si, Sn)O semiconductors having the formula GaₙAlₛInᵣBᵤMgᵥFe_{w}SiₓSn_{y}O_{z} where:

0≤n≤1,0≤s≤1,0≤t≤1,0≤u≤1,0≤v≤1,0≤w≤1,0≤x≤1,0≤y≤1, 0≤z≤1, and n+s+t+u+v+w+x+y+z=1

The UVTC material may comprise one or multiple layers or regions having varying or graded (Ga, Al, In, B, Mg, Fe, Si, Sn)O compositions, or one or more layers or regions of similar (Al, Ga, In, B, Mg, Fe, Si, Sn)O compositions, or a heterostructure comprising layers or regions of dissimilar (Ga, Al, In, B, Mg, Fe, Si, Sn)O compositions.

In one embodiment, the UVTC material may be composed of Ga₂O₃, as well as different structures and/or phases of Ga₂O₃, such as an alpha, beta, gamma, delta, and epsilon phase of Ga₂O₃. Further, the UVTC material may be comprised of a (−201), (001), or (010) crystal orientation of Ga₂O₃.

The UVTC material may be deposited by hydride vapor phase epitaxy (HVPE), metal organic chemical vapor deposition (MOCVD), molecular beam epitaxy (MBE), sputtering, atomic layer deposition (ALD), electron beam deposition (EBD), or another deposition technique, on or above the p-type region 104 or the second n-type region 200.

In one embodiment, the n-type region 101, the p-type region 103, the second n-type region 200, and the UVTC region 105 are all transparent to the UV light emitted from the active region 104. Moreover, the n-type region 101, the p-type region 103, the second n-type region 200, and the UVTC region 105, each has a bandgap larger than the active region 104.

Subsequently, in Block 307, an etch is performed on the regions 101, 102, 103, 104, 105, and 200, in order to expose the n-type region 101. The UVTC region 105 is at least partially etched in order to access the second n-type region 200, wherein at least a portion of the UVTC region 105 is left intact and not etched. In addition, the second n-type region 200 may be at least partially etched in order to access the p-type region 103. This etch can be performed preferably by known methods of mesa etching or by mechanical sawing, laser cutting, and water-jet cutting.

In Block 308, electrodes 106 and 107 are then deposited, wherein the electrodes 106 and 107 can be composed of metals such as gold, nickel, titanium, aluminum, or silver, or a combination thereof.

In Block 309, the structure can then be divided into individual devices on the substrate 100, preferably by known methods of mesa etching or by mechanical sawing, laser cutting, and water-jet cutting, all of which cut through the deposited layers while not cutting through the substrate 100. The individual devices can have different sizes with the suitable range of sizes being 250-300 microns square. In alternative embodiments according to the present invention, the regions 101, 102, 103, 104, 105, and 200 can be left on the substrate 100 as continuous layers, and then divided into individual devices.

In addition, the substrate 100 with its devices can be inverted and flip-chip mounted on a lateral surface of a carrier, and in a preferred embodiment, the devices are bonded in place. The carrier can then be singulated into portions to form light emitting devices separated from one another, with each of the light emitting devices mounted to a respective portion of the carrier.

Subsequently, in Block 310, the substrate 100 can then be removed, wherein the n-type region 101 is exposed by removing the substrate 100 and subsequently can be patterned. The patterns can be comprised of circles, stripes, hexagons, or other patterns.

Finally, Block 311 represents the resulting device(s).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising:
a substrate, an n-type region formed on or above the substrate, an active region formed on or above the n-type region, a p-type region formed on or above the active region, and at least one ultraviolet transparent contact (UVTC) formed on or above the p-type region, wherein the active region emits ultraviolet (UV) light, and the n-type region, the p-type region and the ultraviolet transparent contact are transparent to the UV light.

2. The device of claim 1, wherein the first n-type region, active region, and p-type region, are comprised of AlₓIn_{y}Ga_{1-x-y}N, where 0≤x≤1, 0≤y≤1.

3. The device of claim 1, wherein the ultraviolet transparent contact is comprised of an alloy composition having a formula GaₙAlₛInₜBᵤMgᵥFe_{w}SiₓSn_{y}O_{z} where:
0≤n≤1,0≤x≤1,0≤y≤1,0≤z≤1,and n+s+t+u+v+w+x+y+z=1.

4. The device of claim 3, wherein the ultraviolet transparent contact is comprised of an alpha, beta, gamma, delta, and epsilon phase of Ga₂O₃.

5. The device of claim 4, wherein the ultraviolet transparent contact is comprised of a (−201), (001), or (010) crystal orientation of Ga₂O₃.

6. The device of claim 1, wherein the ultraviolet transparent contact is deposited by hydride vapor phase epitaxy (HVPE), metal organic chemical vapor deposition (MOCVD), molecular beam epitaxy (MBE), sputtering, atomic layer deposition (ALD), electron beam deposition (EBD), or other deposition technique, on or above the p-type region.

7. The device of claim 1, wherein the ultraviolet transparent contact is bonded on or above the p-type layer.

8. The device of claim 1, wherein the n-type region, the p-type region and the ultraviolet transparent contact each has a bandgap larger than the active region.

9. The device of claim 1, wherein the n-type region is a first n-type region, a second n-type region is formed on or above the p-type region, and the ultraviolet transparent contact is formed on or above the second n-type region, wherein the second n-type region is transparent to the UV light.

10. The device of claim 9, wherein the second n-type region forms a tunnel junction with the p-type region.

11. The device of claim 9, wherein the second n-type region has a larger bandgap than the active region.

12. The device of claim 9, wherein the ultraviolet transparent contact is at least partially etched in order to access the second n-type region, and at least a portion of the ultraviolet transparent contact is left intact and not etched

13. The device of claim 12, wherein the second n-type region is at least partially etched in order to access the p-type region.

14. The device of claim 9, wherein the second n-type region is comprised of AlₓIn_{y}Ga_{1-x-y}N, where 0≤x≤1, 0≤y≤1.

15. A method of fabricating an optoelectronic device, comprising:
forming at least one first n-type region on a substrate;
forming at least one active region on or above the n-type region;
forming at least one p-type region on or above the active region; and
forming at least one ultraviolet transparent contact (UVTC) on or above the p-type region;
wherein the active region emits ultraviolet (UV) light, and the n-type region, the p-type region and the ultraviolet transparent contact are transparent to the UV light.

16. The method of claim 15, wherein the first n-type region, active region, and p-type region, are comprised of AlₓIn_{y}Ga_{1-x-y}N, where 0≤x≤1, 0≤y≤1.

17. The method of claim 15, wherein the ultraviolet transparent contact is comprised of an alloy composition having a formula GaₙAlₛInₜBᵤMgᵥFe_{w}SiₓSn_{y}O_{z} where:
0≤n≤1,0≤x≤1,0≤y≤1,0≤z≤1,and n+s+t++u+v+w+x+y+z=1.

18. The method of claim 17, wherein the ultraviolet transparent contact is comprised of an alpha, beta, gamma, delta, and epsilon phase of Ga₂O₃.

19. The method of claim 18, wherein the ultraviolet transparent contact is comprised of a (−201), (001), or (010) crystal orientation of Ga₂O₃.

20. The method of claim 15, wherein the ultraviolet transparent contact is bonded on or above the p-type layer.
